(19) United States
(12) Patent Application Publication
(10) Pub. No.: US 2006/0289904 A1
(43) Pub. Date: Dec. 28, 2006

(54) SEMICONDUCTOR DEVICE AND METHOD OF MANUFACTURING THE SAME

(75) Inventors: Mikio Tsujiuchi, Tokyo (JP); Toshiaki Iwamatsu, Tokyo (JP); Takashi Ipposhi, Tokyo (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: Renesas Technology Corp., Chiyoda-ku (JP)

(21) Appl. No.: 11/425,072

(22) Filed: Jun. 19, 2006

(30) Foreign Application Priority Data
Jun. 24, 2005 (JP) 2005-184295

(51) Int. Cl. H01L 29/76

(52) U.S. Cl. 257/288

(57) ABSTRACT

In the semiconductor device which has partial trench isolation as isolation between elements formed in an SOI substrate, resistance reduction of the source drain of a transistor and reduction of leakage current are aimed at. A MOS transistor is formed in the active region specified by the isolation insulating layer in the SOI layer formed on the buried oxide film layer (BOX layer). An isolation insulating layer is a partial trench isolation which has not reached a BOX layer, and source and drain regions include the first and the second impurity ion which differs in a mass number mutually.

### CROSS-REFERENCE TO RELATED APPLICATION

The present application claims priority from Japanese patent application No. 2005-184295 filed on Jun. 24, 2005, the content of which is hereby incorporated by reference into this application.

### FIELD OF THE INVENTION

The present invention relates to a semiconductor device which has SOI (Silicon-On-Insulator) structure, and its manufacturing method.

### DESCRIPTION OF THE BACKGROUND ART

The SOI device using an SOI substrate which stacks a supporting substrate, an insulator layer, and a silicon layer (SOI layer) in layers attracts attention as a device which can improve the performance of a semiconductor device in recent years. For example, a MOS (Metal-Oxide Semiconductor) transistor formed in the SOI substrate has the small parasitic capacitance of the source and drain regions, and operation of a high speed and low power is possible for it.

Improvement in performance of a MOS transistor formed in a silicon substrate of a bulk also being achieved on the other hand, for example, implanting two kinds of impurity ion in formation of the source and drain regions of a MOS transistor is proposed in following Patent References 1-5.

[Patent Reference 1] Japanese Unexamined Patent Publication No. Hei 10-56171

[Patent Reference 2] Japanese Unexamined Patent Publication No. 2000-232221

[Patent Reference 3] Japanese Unexamined Patent Publication No. 2004-281693

[Patent Reference 4] Japanese Unexamined Patent Publication No. Hei 9-260649

[Patent Reference 5] Japanese Unexamined Patent Publication No. 2003-31798

### SUMMARY OF THE INVENTION

As trench isolation which separates between each element, such as a transistor, in an SOI device, there are full trench isolation (FTI: Full Trench Isolation) which separates an SOI layer thoroughly, and partial trench isolation (PTI: Partial Trench Isolation) formed only in the upper part of an SOI layer.

Especially, in the device structure having PTI, the electric potential of the well (called a “body”) in which a transistor was formed can be controlled through the SOI layer which remains under PTI. Therefore, it is not necessary to form the terminal for controlling body electric potential in the same active region as the transistor, and increase of the parasitic capacitance of the transistor can be prevented. Body electric potential may be dynamically controlled depending on the application of a transistor, although usually fixed to a certain value for the operational stabilization of the transistor.

In order to reduce the parasitic capacitance of the transistor further, it is tended to make an SOI layer further thin, and it will be also needed to make PTI thin according to it. When PTI becomes thin, we will be anxious about the impurity ion concerned penetrating through PTI and reaching even the SOI layer under it in the case of implantation of the impurity ion for forming the source and drain regions of the transistor. When impurity ion penetrates through PTI and an impurity layer of the same conductivity type as the source and drain regions is formed in the SOI layer under PTI, the element isolation function of PTI will be spoiled and it will become a problem.

Therefore, when PTI is thin, it is necessary to perform impurity ion implantation for source and drain region formation with extremely low energy. Therefore, source and drain regions will be formed more shallowly than a conventional device, and the impurity concentration profile will become what has only a high surface portion.

In that case, when the region upper part concerned is made silicide for the purpose of the resistance reduction of the source and drain regions, the surface portion with high impurity concentration will be made silicide. That is, the impurity concentration in the boundary face of the formed silicide layer and the source and drain regions will become low. As a result, the connection resistance of the silicide layer and the source and drain regions becomes high, and the problem of it becoming impossible to aim at resistance reduction of the source and drain regions which is the original purpose of silicide formation occurs.

Since the source and drain regions are shallow, the distance of the pn junction surface in the bottom and the silicide layer becomes near. Thereby, the junction capacitance in the source and drain regions becomes large, and the problem that leakage current will increase occurs.

The present invention is made in order to solve the above problems, and aims at offering a semiconductor device in which the resistance reduction of the source drain of the transistor and reduction of leakage current are possible while aiming at thickness reduction of an SOI layer in the semiconductor device which has PTI structure as an isolation between elements formed in an SOI substrate.

A semiconductor device concerning the present invention comprises: a semiconductor layer formed over an insulator layer; an isolation insulating layer which is formed in the semiconductor layer and specifies an active region in the semiconductor layer concerned; a transistor which has source and drain regions formed in the active region; and a silicide layer formed in the source and drain region upper part of the transistor; wherein the isolation insulating layer has a portion which does not reach the insulator layer; and the source and drain regions include a first and a second impurity ions with which mass numbers differ mutually.

A method of manufacturing a semiconductor device concerning the present invention comprises the steps of: (a) forming an isolation insulating layer which specifies an active region in a semiconductor layer to the semiconductor layer concerned formed over an insulator layer; (b) forming a gate electrode of a transistor in the active region; (c) forming source and drain regions of the transistor in the active region by implanting a first impurity ion with a comparatively small mass number, and a second impurity ion with a comparatively large mass number in an order of a small mass number; (d) diffusing the first and the second impurity ions of the source and drain regions by heat treatment; and (e) forming a silicide layer in the source and drain region upper part; wherein in the step (a), the isolation insulating layer is formed so that at least a portion may not reach even the insulator layer; and implantation conditions of the first and the second impurity ions in the step (c) is set up so that a concentration of the first impurity ion may become more than a concentration of the second impurity ion in a boundary face of the silicide layer and the source and drain regions after the step (d) and (e).

According to the semiconductor device concerning the present invention, since source drain regions include the first and the second impurity ions with which mass numbers differ mutually, the source and drain regions come to have an impurity concentration profile gradual and at high concentration, and a deep profile. That is, impurity concentration in the depth of a boundary face with a silicide layer in the source and drain regions can be made high, and the distance of the pn junction surface of the source and drain region bottom and the silicide layer can be detached. Therefore, resistance reduction between silicide layer-source and drain regions can be aimed at, and it is possible to reduce the leakage current by the junction capacitance of the source and drain regions.

According to the manufacturing method of the semiconductor device concerning the present invention, since the concentration of the first impurity ion becomes more than the concentration of the second impurity ion in the boundary face of a suicide layer and source and drain regions after a heat treatment, the impurity concentration of the boundary face concerned becomes high and resistance reduction between suicide layer-source and drain regions can be aimed at. Since the first and the second impurity ions are implanted in an order of a small mass number, the first impurity ion can be more deeply implanted with low energy by channeling. Therefore, since the source and drain regions can be formed by a deep profile, the distance of the pn junction surface of the source and drain region bottom and the silicide layer can be detached, and the leakage current by the junction capacitance of the source and drain regions can be reduced.

### BRIEF DESCRIPTION OF THE DRAWINGS

FIG. 1 is a top view showing the structure of the semiconductor device concerning Embodiment 1;

FIGS. 2 and 3 are cross-sectional views showing the structure of the semiconductor device concerning Embodiment 1;

FIGS. 4 to 10 are process drawings showing the manufacturing method of the semiconductor device concerning Embodiment 1;

FIG. 11 is a drawing showing the impurity concentration profile immediately after the source and drain region formation in the semiconductor device concerning Embodiment 1;

FIGS. 12 and 13 are process drawings showing the manufacturing method of the semiconductor device concerning Embodiment 1;

FIG. 14 is a drawing showing the impurity concentration profile in the semiconductor device concerning Embodiment 1;

FIG. 15 is a drawing showing the impurity concentration profile in a conventional semiconductor device;

FIG. 16 is a drawing showing an example of the experimental result of the semiconductor device concerning Embodiment 1;

FIGS. 17 to 19 are drawings showing the modification of Embodiment 1;

FIG. 20 is a drawing for explaining the manufacturing method of the semiconductor device concerning Embodiment 2; and

FIG. 21 is a drawing for explaining the manufacturing method of the semiconductor device concerning Embodiment 3.

### DETAILED DESCRIPTION OF THE PREFERRED EMBODIMENTS

### Embodiment 1

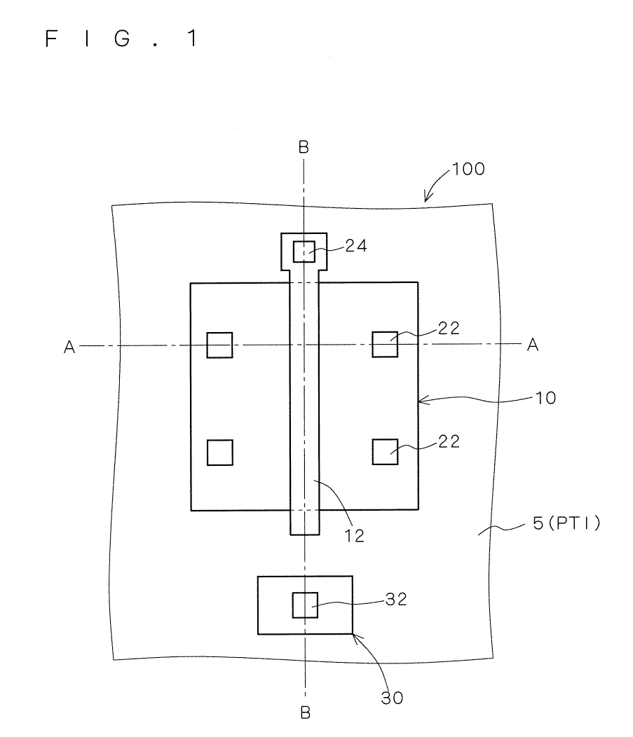

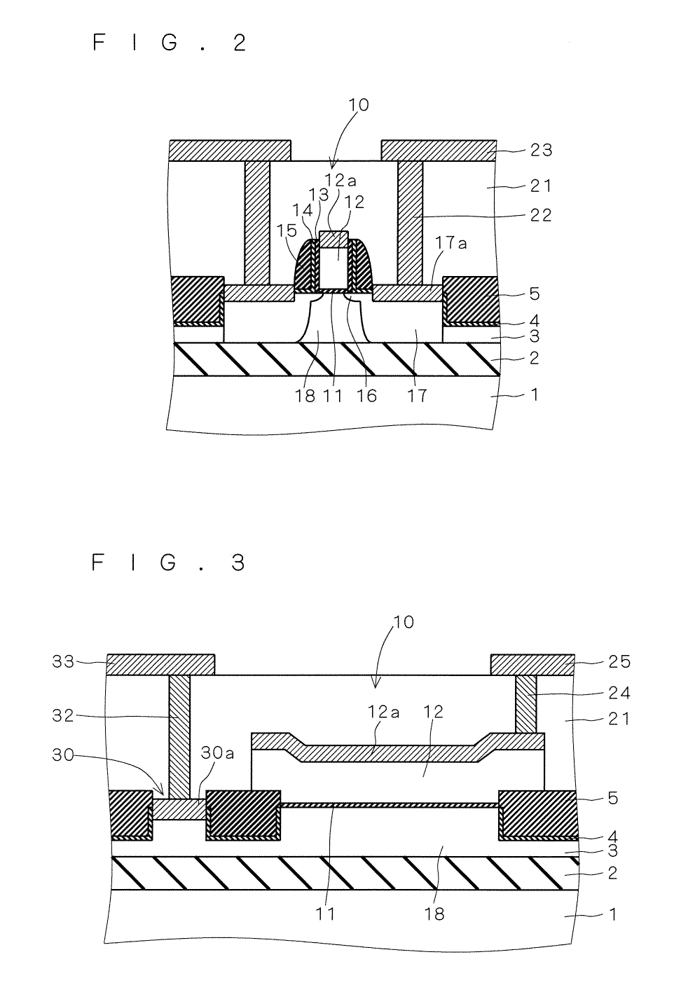

FIG. 1-FIG. 3 are the drawings showing the structure of the semiconductor device concerning Embodiment 1 of the present invention. FIG. 1 is a top view of the MOS transistor with which the semiconductor device concerned is provided, and FIG. 2 and FIG. 3 are the cross-sectional views which are taken along the A-A line and the B-B line of FIG. 1, respectively. Through these drawings, the same reference is given to the same element.

The semiconductor device concerning this embodiment has MOS transistor 10, and cell 30 for body electric-potential fixation which is a terminal (body terminal) for setting up the body electric potential on SOI substrate 100 like FIG. 1. Here, on the convenience of explanation, the explanation is made, assuming that MOS transistor 10 is an n channel type transistor (nMOS transistor). However, although also mentioning later, the present invention is applicable also to a p channel type transistor (pMOS transistor).

With reference to FIG. 2 and FIG. 3, above-mentioned SOI substrate 100 is formed, stacking supporting substrate 1 of silicon, buried oxide film (following “BOX layer”) 2 as an insulator layer, and silicon layer (following “SOI layer”) 3 as a semiconductor layer in layers. Isolation insulating layer 5 is formed in SOI layer 3, and the isolation insulating layer 5 concerned has silicon oxide film 4 in the boundary face with SOI layer 3. Isolation insulating layer 5 does not reach even BOX layer 2 under SOI layer 3, namely, is PTI.

MOS transistor 10 is formed in the active region specified by isolation insulating layer 5 in SOI layer 3. MOS transistor 10 has gate insulating film 11 formed on SOI layer 3, and gate electrode 12 formed on the gate insulating film 11 concerned. Silicide layer 12a is formed in the upper part of gate electrode 12, and spacer oxide film 13, sidewall oxide film 14, and sidewall nitride film 15 are formed on the both side surfaces of gate electrode 12, respectively. MOS transistor 10 has source and drain regions 17 and extension region 16 in SOI layer 3, and silicide layer 17a is formed in the upper part of source and drain regions 17.

When MOS transistor 10 is an nMOS transistor, the extension region 16 and source and drain regions 17 are n type regions, and body region 18 is a p type region. With reference to FIG. 3, SOI layer 3 under isolation insulating layer 5 and cell 30 for body electric-potential fixation are p type regions. That is, cell 30 for body electric-potential fixation has electrically connected with body region 18 of MOS transistor 10 via SOI layer 3 under isolation insulating layer 5, and functions as a body terminal which can set up the electric potential of the body region 18 concerned. Silicide layer 30a is formed in the upper part of cell 30 for body electric-potential fixation.

On SOI layer 3, interlayer insulating film 21 is formed so that MOS transistor 10 and cell 30 for body electric-potential fixation may be covered. Contacts 22, 24, and 32 are formed in interlayer insulating film 21, and it has connected with wirings 23, 25, and 33 formed on interlayer insulating film 21, respectively. Like FIG. 2, source and drain regions 17 are connected to contact 22 via silicide layer 17a. Like FIG. 3, gate electrode 12 is connected to contact 24 via silicide layer 12a. Cell 30 for body electric-potential fixation is connected to contact 32 via silicide layer 30a.

In this embodiment, source and drain regions 17 of MOS transistor 10 include two sorts of n type impurity ion with which mass numbers differ mutually. More concretely, it includes a phosphorus (P) ion as the first impurity ion with a comparatively small mass number, and an arsenic (As) ion as the second impurity ion with a comparatively large mass number.

Since the mass number is comparatively small, P ion has long range, and it tends to cause channeling. Therefore, since it is deeply implanted even with low energy, it is difficult to form the high-concentration source and drain regions. Since As ion has short range since the mass number is comparatively large, and it is hard to cause channeling, source and drain regions can be formed with high concentration and shallowly easily. Therefore, since SOI layer thickness became thin (for example, about 100 nm or less), when PTI was made thin, P ion was not usually used for formation of source and drain regions, but As ion was used.

However, in the source and drain regions formed only with As ion, since As ion hardly diffuses in annealing for activation of an impurity, only the surface portion of source and drain regions will become high concentration as a result. Therefore, as stated previously, when the upper part of the source and drain regions is made silicide, a problem that the impurity concentration in the boundary face of the silicide layer and the source and drain regions becomes low, and the connection resistance of the silicide layer and the source and drain regions concerned will become high, and a problem that leakage current will increase when the distance of the pn junction surface of the source and drain region bottom and the silicide layer becomes near had occurred.

Since source and drain regions 17 include two, P ion and As ion with which mass numbers differ mutually, according to this embodiment, the high-concentration impurity concentration profile which was difficult only with P ion is realizable. Since it is easy to make thermal diffusion of the P ion by heat treatment, the gradual impurity concentration profile and the deep profile which were difficult only with conventional As ion are realizable. That is, according to this embodiment, impurity concentration in the depth (the depth of about 50 nm from the surface of SOI layer 3) of the boundary face with silicide layer 17a in source and drain regions 17 can be made high, and the distance of the pn junction surface of source and drain region 17 bottom and silicide layer 17a can be detached. Therefore, resistance reduction between silicide layer 17a-source and drain regions 17 can be aimed at, and it is possible to reduce the leakage current by the junction capacitance of source and drain regions 17.

That is, avoiding the two above-mentioned problems of the resistance increase between silicide layer 17a-source and drain regions 17, and increase of leakage current, the parasitic capacitance of MOS transistor 10 can be reduced further, and it can contribute to speeding up and lowering of power consumption of a semiconductor device greatly. In the conventional MOS transistor, when SOI layer thickness became thin to about 100 nm or less, the two above-mentioned problems had the tendency to become remarkable. Therefore, in this embodiment, it can be said that application in the thin SOI layer of 100 nm or less is especially effective.

Since pn junction will not be formed in the bottom concerned when diffusing source and drain regions 17 especially like FIG. 2 in this embodiment so that the bottom may reach even BOX layer 2, junction capacitance in source and drain regions 17 can be made very small, and a high effect is acquired by the reduction of leakage current.

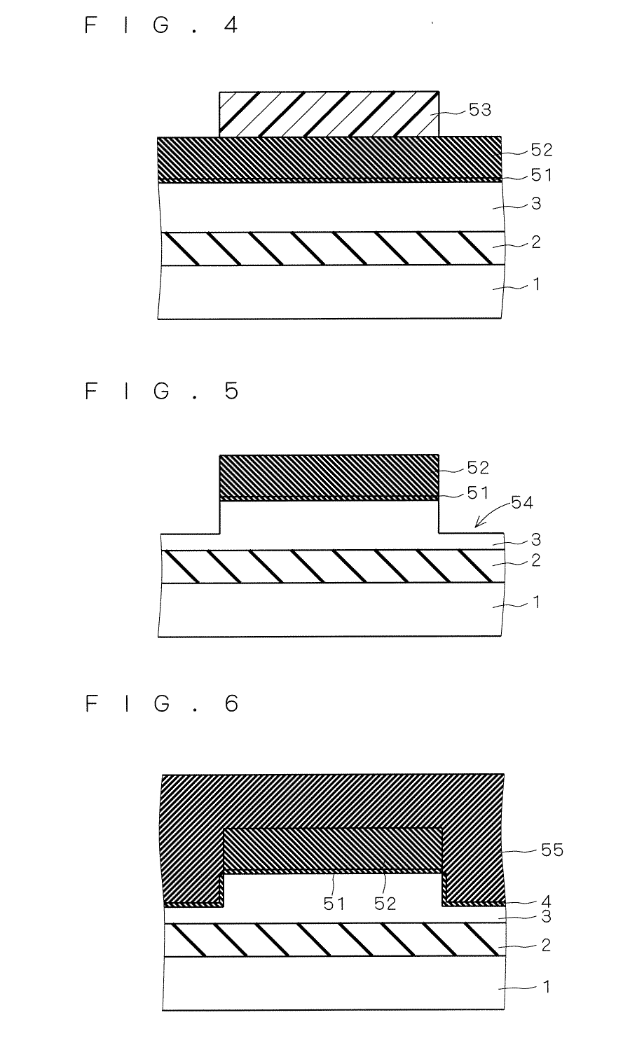

Next, with reference to process drawings shown in FIG. 4-FIG. 10 and FIG. 12, and FIG. 13, the formation method of MOS transistor 10 concerning this embodiment is explained. In these process drawings, the same reference is given to the same element as FIG. 1-FIG. 3.

First, an SOI substrate stacking supporting substrate 1, BOX layer 2, and SOI layer 3 in layers is prepared. The thickness of SOI layer 3 is about 30 nm-200 nm, for example. And on SOI layer 3, silicon oxide film 51 and silicon nitride film 52 are formed one by one, a resist layer is applied to the whole surface after that, and resist pattern 53 is formed with a photoengraving process technology (photo lithography technology) (FIG. 4).

And trench 54 for forming isolation insulating layer 5 is formed by etching silicon nitride film 52, silicon oxide film 51, and SOI layer 3 by using resist pattern 53 as a mask. Since isolation insulating layer 5 is PTI, etched depth at this time is made into extent with which SOI layer 3 remains under trench 54 (FIG. 5).

Even if it is the case that SOI layer 3 is thin, when making trench 54 deep, the thickness of isolation insulating layer 5 can be earned to some extent. However, since SOI layer 3 under isolation insulating layer 5 functions as a wiring for applying the electric potential of cell 30 for body electric-potential fixation to body region 18 as shown in FIG. 3, when SOI layer 3 under isolation insulating layer 5 is made thin too much, resistance will increase and the electric potential of body region 18 will become unstable. Therefore, as thickness of SOI layer 3 under isolation insulating layer 5, it is desirable to secure about at least 30 nm.

Then, the inner wall of trench 54 is oxidized and silicon oxide film 4 of about 5 nm-50 nm of thickness is formed (when silicon oxide film 4 is unnecessary on the surface of isolation insulating layer 5, it is not necessary to perform this process step). And silicon oxide film 55 is formed in the whole surface so that trench 54 may be buried (FIG. 6). At this time, annealing of 500° C. to 1300° C. performs thermally tightening according to need. Isolation insulating layer 5 is formed by removing silicon oxide film 55 by the CMP method to extent to which silicon nitride film 52 appears in the upper surface, and etching removes silicon nitride film 52 after that. And after performing the ion implantation for well formation, silicon oxide film 51 is removed (FIG. 7).

And thin silicon oxide film 56 is formed in the SOI layer 3 upper surface, and polysilicon film 57 is deposited on it (FIG. 8). Silicon oxide layer 56 and polysilicon film 57 are patterned by etching using a photo lithography technology, and gate insulating film 11 and gate electrode 12 are formed. And spacer oxide film 13 is formed on the side face of gate electrode 12, As ion is implanted into SOI layer 3, and extension region 16 (n-region) is formed (FIG. 9). And pocket implantation is performed according to need.

Then, sidewall oxide film 14 and sidewall nitride film 15 are formed on the side face of gate electrode 12 by forming a silicon oxide film and a silicon nitride film in the whole surface one by one, and etching back them. And by an ion implantation, source and drain regions 17 which are n+ regions are formed (FIG. 10).

As mentioned above, source and drain regions 17 of this embodiment include P ion and As ion which are the impurity ion with which mass numbers differ mutually. Especially by this embodiment, P ion (first impurity ion) and As ion (second impurity ion) are implanted sequentially from the one where a mass number is smaller. That is, P ion is implanted first. At this time, the implantation energy of the grade that P ion does not degrade the isolation characteristics of isolation insulating layer 5 by penetrating through isolation insulating layer 5 is chosen. Subsequently, As ion is implanted. Also at this time, the implantation energy of the grade that the As ion concerned does not degrade the isolation characteristics of isolation insulating layer 5 by penetrating through isolation insulating layer 5 is chosen.

P ion with a small mass number is previously implanted as order of implantation in order to make channeling cause in the case of the implantation and to implant P ion into SOI layer 3 more deeply with low energy. That is, when As ion is implanted in large quantities previously, SOI layer 3 will become amorphous. Since it becomes difficult to generate channeling even if P ion is implanted after that, it is not desirable.

Although the forming step (FIG. 9) of extension region 16 by As ion implantation is performed prior to the forming step of source and drain regions 17 in this embodiment, since the implantation amount of As ion in the step is extent by which SOI layer 3 is not made amorphous, it does not become the hindrance of channeling in P ion implantation for source and drain region 17 formation.

Therefore, it is necessary to perform implantation of P ion perpendicularly to the upper surface of SOI layer 3 so that the direction of implantation may go along the crystal orientation of SOI layer 3. P ion can be implanted into the active region of SOI layer 3 deeply, preventing penetrating through isolation insulating layer 5 by implanting P ion so that channeling may happen in SOI layer 3, since channeling is not generated within isolation insulating layer 5.

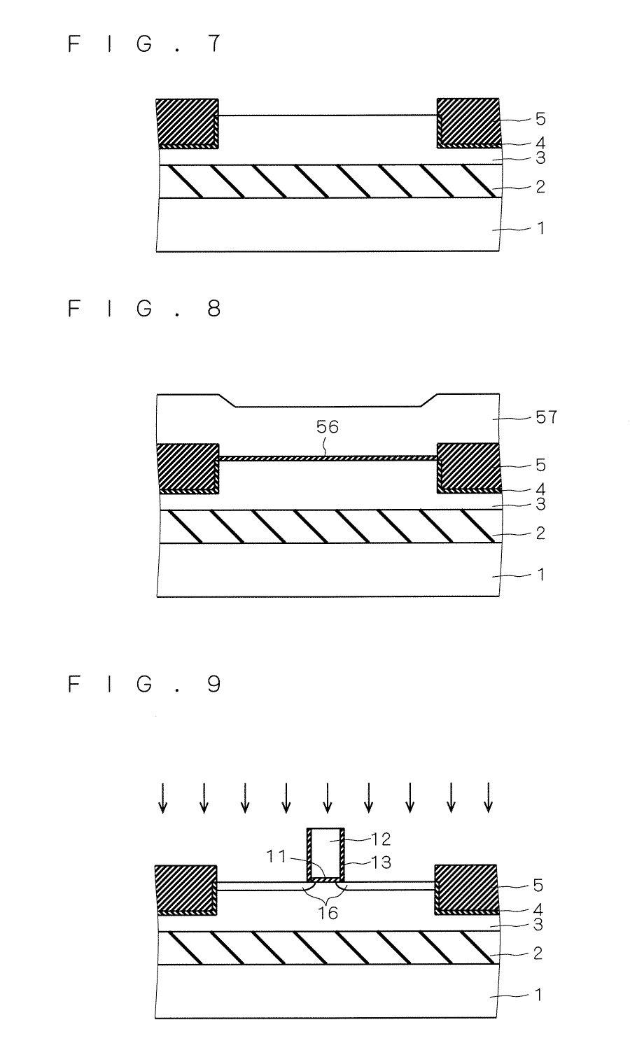

FIG. 11 is a drawing showing the impurity concentration profile of the source and drain regions 17 concerned immediately after the implantation step of P ion and As ion for source and drain region 17 formation of MOS transistor 10. Each impurity concentration profile of P ion and As ion to the depth of source and drain regions 17 along the C-C line shown in FIG. 11 concretely is shown. As shown in the same drawing, in the implantation step of P ion and As ion, they are implanted to the depth (namely, depth which does not penetrate through isolation insulating layer 5) which does not reach even the bottom of isolation insulating layer 5. P ion is implanted by channeling at the time of implantation more deeply than As ion.

Here, in order to prevent the penetration through isolation insulating layer 5 of P ion and As ion, the one where isolation insulating layer 5 is thicker is desirable. However, in order that it is necessary to secure the moderate thickness (for example, about 30 nm or more) of SOI layer 3 under isolation insulating layer 5, there is a limitation in forming isolation insulating layer 5 deeply. Then, like FIG. 10, from SOI layer 3, the upper part is made to project and isolation insulating layer 5 is thickened. However, when height h for a projecting portion of this isolation insulating layer 5 is too high, at the time of patterning of gate electrode 12, we are anxious about the residual substance of polysilicon remaining in the level difference portion of SOI layer 3 and isolation insulating layer 5. Therefore, it is desirable for the above-mentioned height h to be high as much as possible in the range of preventing it (about 50 nm).

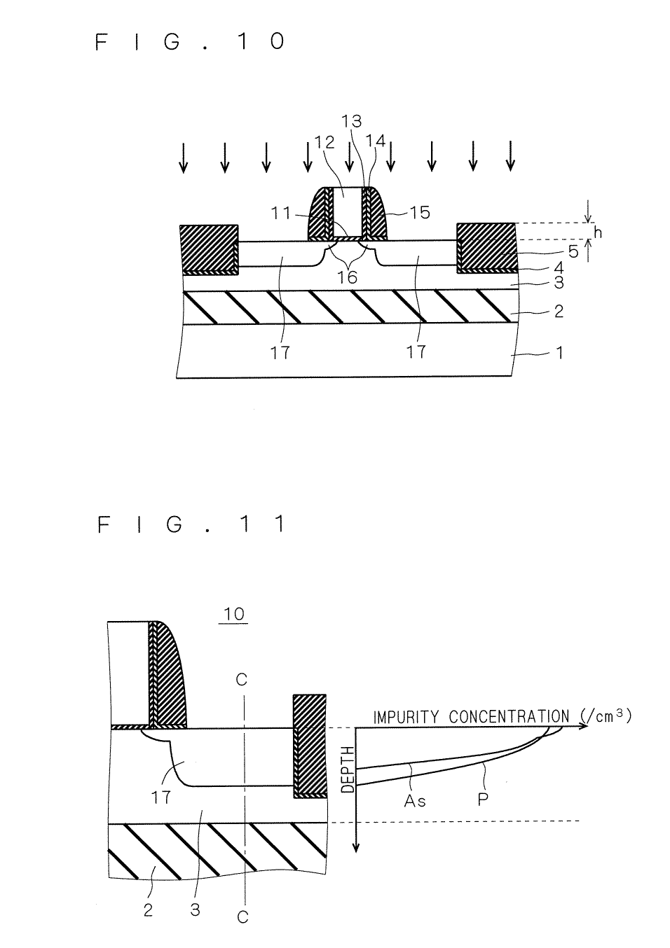

Annealing for activating P ion and As ion which were implanted is performed after formation of source and drain regions 17. This annealing is effective in diffusing P ion and As ion in source and drain regions 17. Since P ion which is easy to diffuse with heat is implanted into source and drain regions 17 of this embodiment, source and drain regions 17 diffuse until they reach BOX layer 2 (FIG. 12).

Then, silicide layers 12a and 17a are formed in the upper part of gate electrode 12 and source and drain regions 17, respectively by making metal, such as cobalt and nickel, accumulate and react on MOS transistor 10 (FIG. 13).

And after removing the unreacted metal, interlayer insulating film 21 is formed by a silicon oxide film, and CMP performs flattening of the upper surface. And a contact hole is formed in interlayer insulating film 21 using a photo lithography technology, and contacts 22, 24, and 32 are formed by embedding metal, such as tungsten, in it. Finally, by depositing wiring materials, such as copper, on interlayer insulating film 21 and forming wirings 23, 25, and 33 by patterning with a photo lithography technology, MOS transistor 10 shown in FIG. 2 is formed.

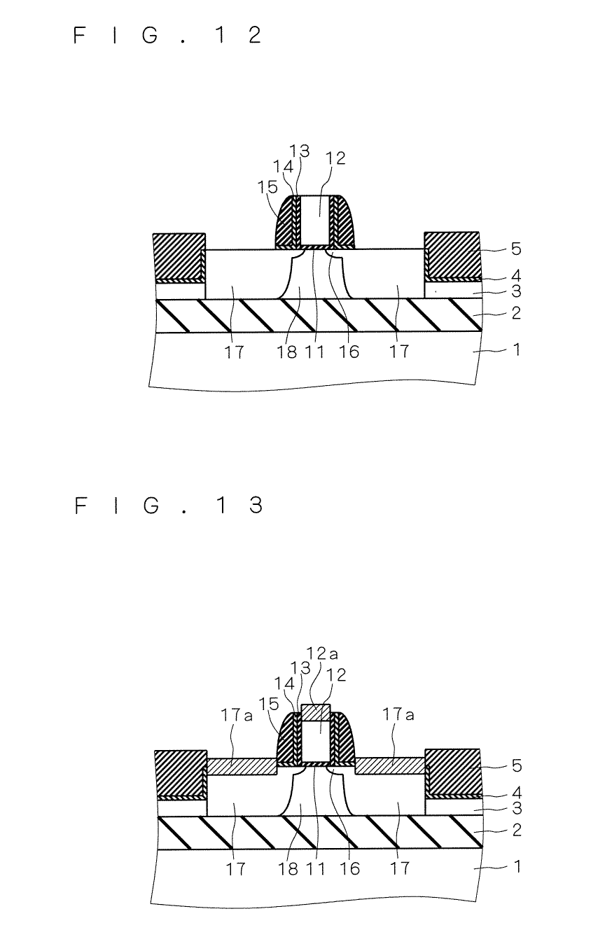

FIG. 14 is a drawing showing the impurity concentration profile of source and drain regions 17 after the above-mentioned annealing step and a silicide forming step. Concretely, the impurity concentration profile of each P ion and As ion to the depth of source and drain regions 17 along the C-C line shown in the same drawing is shown. Even if As ion passes through annealing, it does not diffuse so much, as it can be understood as compared with FIG. 11, but P ion greatly diffuses by the annealing concerned.

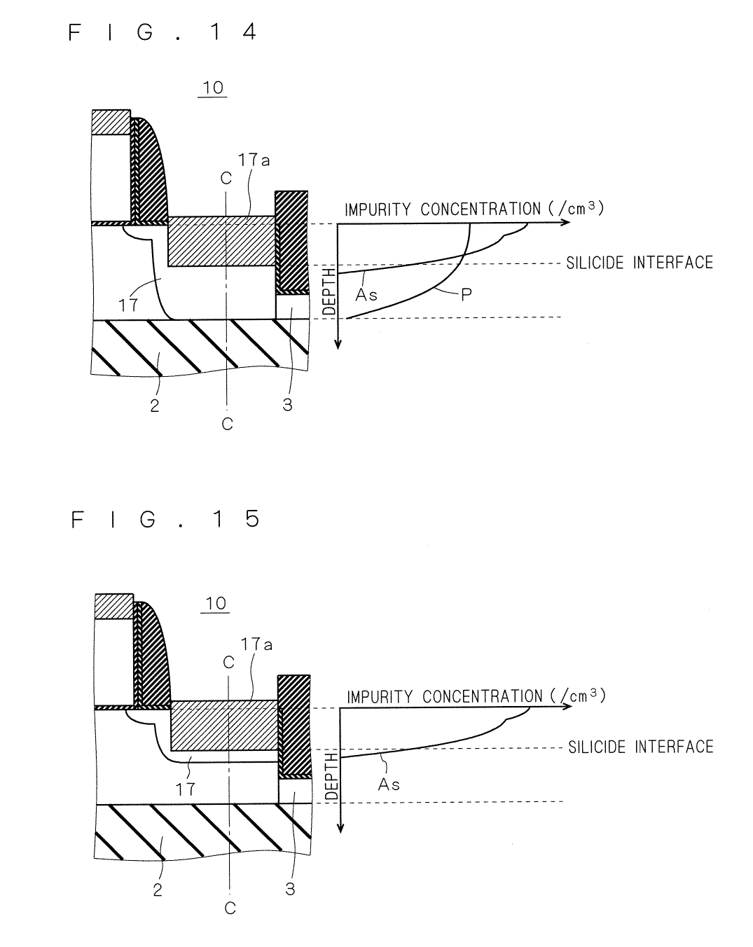

The impurity concentration profile of source and drain regions 17 in a conventional semiconductor device is shown in FIG. 15. As mentioned above, when PTI was adopted as isolation insulating layer 5, only As ion was used for formation of source and drain regions 17. Since As ion did not diffuse so much even if it passed through annealing, the impurity concentration in the boundary face of silicide layer 17a and source and drain regions 17 (silicide boundary face) was low like FIG. 15. Therefore, the problem that the connection resistance between silicide layer 17a-source and drain regions 17 became high had occurred.

Since P ion and As ion are implanted into source and drain regions 17 in this embodiment to it, the impurity concentration (sum of P ion concentration and As ion concentration) in the boundary face of silicide layer 17a and source and drain regions 17 becomes high. Therefore, the connection resistance between suicide layer 17a-source and drain regions 17 can be suppressed low.

Since source and drain regions 17 include P ion which is easy to make thermal diffusion, source and drain regions 17 can be made into a profile deeper than before by annealing. As a result, the distance of the pn junction surface of source and drain region 17 bottom and suicide layer 17a separates, and it becomes possible to reduce the leakage current resulting from the junction capacitance of source and drain regions 17. Since pn junction will not be formed in the bottom of source and drain regions 17 especially when making diffusion of P ion reach even BOX layer 2 like FIG. 14, junction capacitance in source and drain regions 17 can be made very small, and a higher effect is acquired by reduction of leakage current.

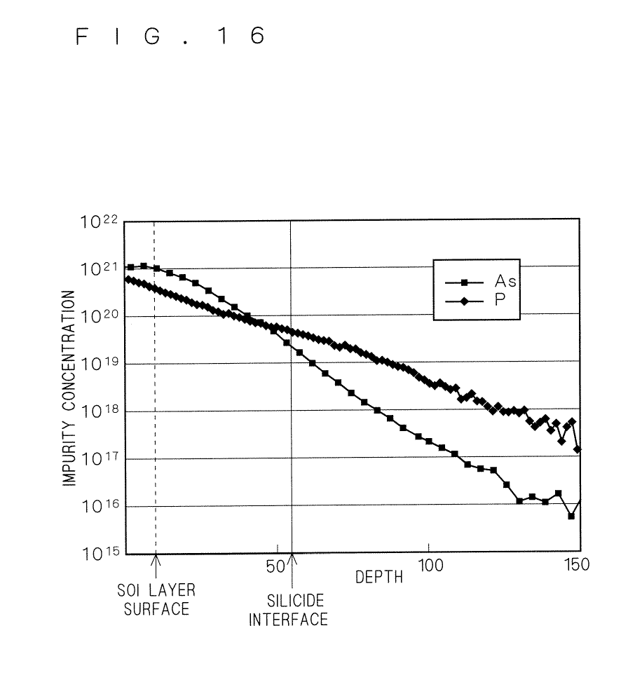

The present inventor etc. conducted the experiment which measures the impurity concentration profile in the source and drain regions of the actually formed MOS transistor, in order to define the conditions from which the effect of this invention is acquired better. FIG. 16 is a graph which shows an example of the experimental result. The concentration distribution of P ion and As ion to the depth direction of the source and drain regions was able to be measured using secondary-ion-mass-spectroscopy (SIMS: Secondary Ion Mass Spectrometry). The measurement concerned is performed, after forming source and drain regions and performing annealing treatment (after the thermal diffusion of P ion and As ion). As a result of the above-mentioned experiment, when P ion concentration becomes more than As ion concentration like FIG. 16 in the depth (the depth of the SOI layer 3 surface to about 50 nm) of the silicide layer boundary face in the source and drain regions after annealing, the result that connection resistance of source and drain regions and a silicide layer could be made low enough was obtained.

Although the present invention is turned to the semiconductor device which has PTI, the whole isolation insulating layer 5 which specifies the active region of MOS transistor 10 as shown in FIG. 1-FIG. 3 does not need to be PTI. That is, when isolation insulating layer 5 has at least PTI structure (structure where BOX layer 2 is not reached), in part, the effect of the present invention will be acquired. In other words, the hybrid trench isolation (HTI: hybrid trench isolation) which combined PTI and FTI may be adopted as isolation insulating layer 5.

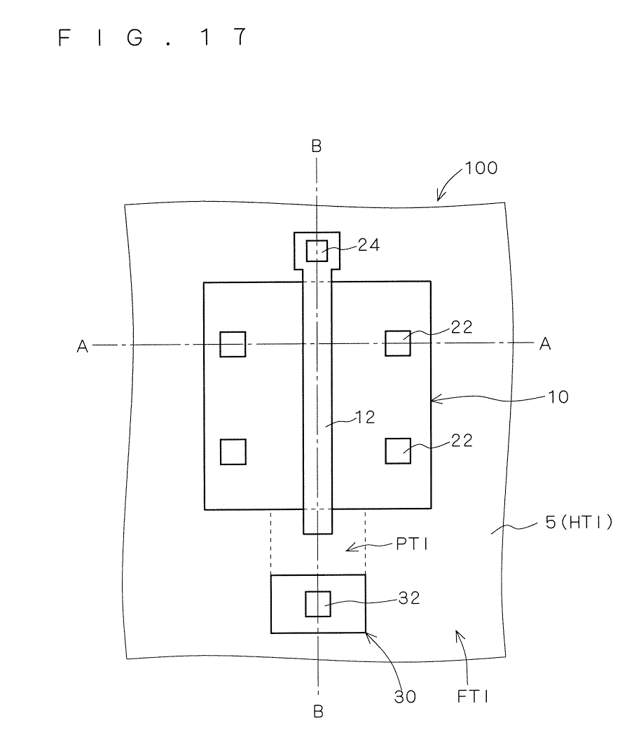

FIG. 17-FIG. 19 are the drawings showing the modification of this embodiment, and are the example which adopted HTI as isolation insulating layer 5. FIG. 17 is a top view of the MOS transistor of the modification concerned, and FIG. 18 and FIG. 19 are the cross-sectional views which are taken along the A-A line and B-B line of FIG. 17, respectively. In these drawings, since the same reference is given to the element corresponding to what was shown in FIG. 1-FIG. 3, detailed explanation here is omitted.

In this modification, like FIG. 17, the portion between MOS transistor 10 and cell 30 for body electric-potential fixation is set to PTI, and the other portion is set to FTI. That is, in the cross section taken along the A-A line, isolation insulating layer 5 becomes the structure which reached even BOX layer 2 (FIG. 18). In the cross section taken along the B-B line, although isolation insulating layer 5 does not reach BOX layer 2 in the cell 30 side for body electric-potential fixation of MOS transistor 10, it becomes the structure attained to BOX layer 2 in the opposite side. It is clear that it is possible to make small connection resistance between silicide layer 17a-source and drain regions 17, without degrading the isolation characteristics in the portion of PTI concerned like this modification, even when isolation insulating layer 5 is PTI partially.

In the above explanation, although MOS transistor 10 was explained as an nMOS transistor, the present invention is applicable also to a pMOS transistor. What is necessary is just to adopt two sorts from which a mass number differs mutually as ion for forming source and drain regions 17 also in the case. It is desirable to implant sequentially from what has a small mass number in the case of formation of source and drain regions 17, in order to make channeling cause. It is possible to adopt B (boron) ion as first ion with a comparatively small mass number, and to adopt BF₂ (boron fluoride) or In (indium) ion as second ion with a comparatively large mass number concretely.

### Embodiment 2

In order to prevent degradation of the isolation characteristics, it is necessary to make the impurity ion implanted in the case of source and drain region 17 formation not penetrate through isolation insulating layer 5, when PTI is adopted as isolation insulating layer 5, as stated previously. In order to suppress this penetration, it is possible to thicken isolation insulating layer 5, but since SOI layer 3 under the isolation insulating layer 5 concerned needs to secure moderate thickness, there is a limitation in forming isolation insulating layer 5 deeply. Then, it is possible to make high the height (height h shown in FIG. 10) of the portion to which isolation insulating layer 5 projects from the substrate. However, since it is necessary to prevent that the residual substance of polysilicon remains in the case of patterning of gate electrode 12 into the level difference portion of SOI layer 3 and isolation insulating layer 5, there is a limitation also in it.

Thus, when the thickness reduction of SOI layer 3 progresses, it will become difficult to form isolation insulating layer 5 thickly. As a result, it will be necessary to set up very small the energy in implantation of the impurity ion for source and drain region 17 formation, and the margin will become small. Therefore, it becomes difficult to form source and drain regions 17 with sufficient accuracy, preventing the penetration through isolation insulating layer 5 of impurity ion. The technology for solving this problem is proposed in this embodiment.

In Embodiment 1 shown previously, sidewall oxide film 14 and sidewall nitride film 15 of a side face of gate electrode 12 were formed by forming the silicon oxide film used as sidewall oxide film 14 and the silicon nitride film used as sidewall nitride film 15 on the entire substrate one by one, and etching back them. In Embodiment 1, like FIG. 10, in the case of the etch back concerned, the upper surface of SOI layer 3 used as source and drain regions 17 was exposed, and the ion implantation for source and drain region 17 formation was performed in that state.

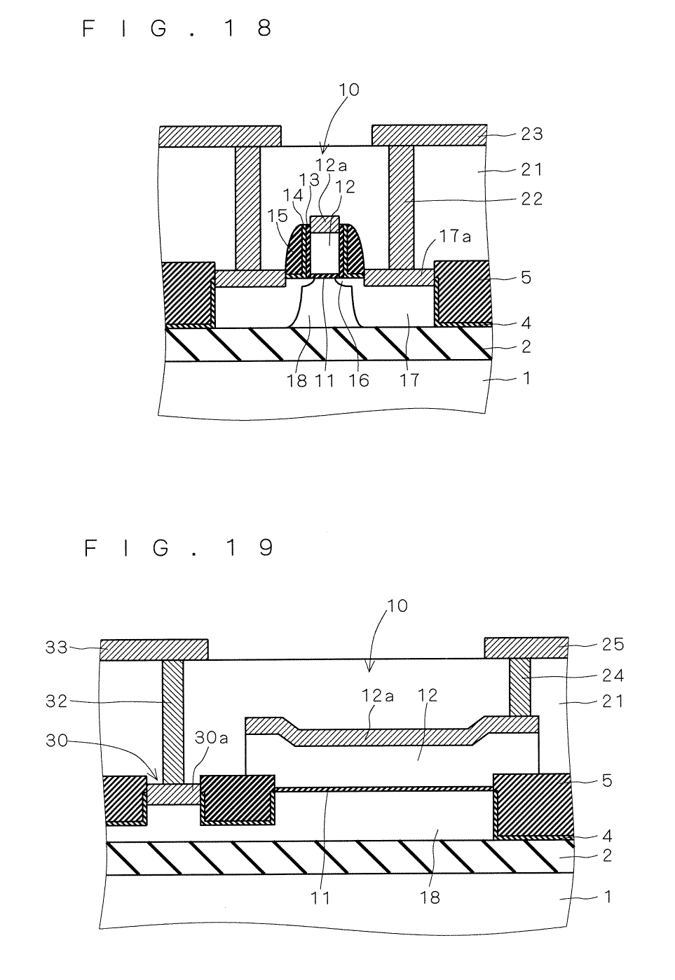

To it, in the above-mentioned etch back process, as shown in FIG. 20, by Embodiment 2, silicon oxide film 114 used as sidewall oxide film 14 is made not to be removed. And the ion implantation for source and drain region 17 formation is performed through the silicon oxide film 114 concerned with the state where the silicon oxide film 114 concerned covered the upper surface of gate electrode 12, SOI layer 3, and isolation insulating layer 5. That is, in the case of the ion implantation for source and drain region 17 formation, silicon oxide film 114 remains on the upper surface of isolation insulating layer 5.

Therefore, the thickness of isolation insulating layer 5 in the ion-implantation step for source and drain region 17 formation becomes thick only the part of the thickness of silicon oxide film 114 substantially. Therefore, it becomes difficult to generate that the implanted impurity ion penetrates through isolation insulating layer 5, and the margin of the energy of the impurity ion implantation concerned becomes large. Therefore, even when isolation insulating layer 5 is thin, formation of the semiconductor device concerning the present invention can be made easy, and it can contribute also to the thickness reduction of an SOI layer in an SOI device.

As Embodiment 1 explained using FIG. 10, when height h of the portion projected from SOI layer 3 of isolation insulating layer 5 is made high, the problem that the residual substance of polysilicon remains in the level difference portion of SOI layer 3 and isolation insulating layer 5 in the case of patterning of gate electrode 12 will occur. Since the substantial thickness of isolation insulating layer 5 is increased using silicon oxide film 114 formed after patterning of gate electrode 12, without making the height h high by this embodiment to it, it is not accompanied by the problem.

In this embodiment, it is good to perform annealing (it corresponds to the step of the FIG. 12 in Embodiment 1) performed after source and drain region 17 formation while covering the upper surface of source and drain regions 17 by silicon oxide film 114. Thereby, the out-diffusion of the impurity in source and drain regions 17 is suppressed, lowering of the impurity concentration of source and drain regions 17 can be prevented, and it is effective for improvement in the electrical property of MOS transistor 10.

When there is no need of suppressing the out-diffusion of source and drain regions 17, annealing may be performed after removing silicon oxide film 114 of the source and drain region 17 upper surface.

When forming silicide layers 12a and 17a on the upper part of gate electrode 12 and source and drain regions 17, respectively, since it is necessary to deposit metal directly on gate electrode 12 and source and drain regions 17, in the case, it is needed to remove silicon oxide film 114 on gate electrode 12 and source and drain regions 17 by etching.

Except the step explained above, it is good to be the same as that of the manufacturing method in Embodiment 1.

### Embodiment 3

In above-mentioned Embodiment 2, substantial thickness of isolation insulating layer 5 in the ion-implantation step for source and drain region 17 formation was thickened by using silicon oxide film 114 used as sidewall oxide film 14.

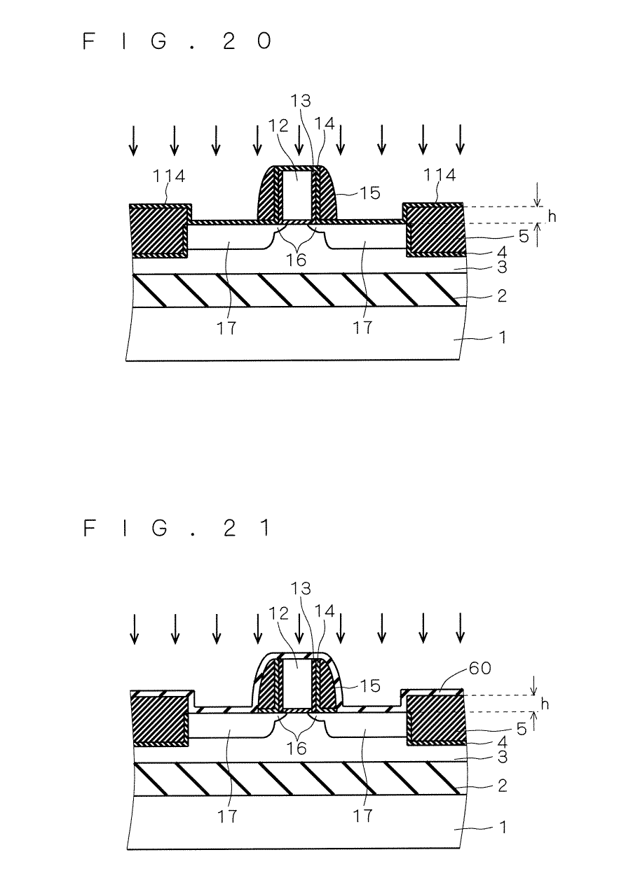

In Embodiment 3, spacer oxide film 13 and sidewall oxide film 14 are formed like Embodiment 1. That is, the forming portions of the source and drain regions 17 concerned in SOI layer 3 are exposed in the case of formation of spacer oxide film 13 and sidewall oxide film 14. And after that, silicon oxide film 60 is separately deposited on the whole surface like FIG. 21, and the ion implantation for source and drain region 17 formation is performed through the silicon oxide film 60 concerned. That is, in the case of the ion implantation for source and drain region 17 formation, silicon oxide film 60 is formed on the upper surface of isolation insulating layer 5.

That is, the thickness of isolation insulating layer 5 in the ion-implantation step for source and drain region 17 formation becomes thick only the part of the thickness of silicon oxide film 60 substantially. Therefore, it becomes difficult to generate that the implanted impurity ion penetrates through isolation insulating layer 5, and the margin of the energy of the impurity ion implantation concerned becomes large. Therefore, formation of the semiconductor device concerning the present invention can be made easy like Embodiment 2, and it can contribute also to the thickness reduction of the SOI layer in an SOI device.

This embodiment has also increased the substantial thickness of isolation insulating layer 5 using silicon oxide film 60 formed after patterning of gate electrode 12, without making high height h of the portion projected from SOI layer 3 of isolation insulating layer 5. Therefore, it is not accompanied by the problem that the residual substance of polysilicon will remain in the level difference portion of SOI layer 3 and isolation insulating layer 5 in the case of patterning of gate electrode 12.

In this embodiment, it is good to perform annealing (it corresponds to the step of the FIG. 12 in Embodiment 1) performed after source and drain region 17 formation while covering the upper surface of source and drain regions 17 by silicon oxide film 60. Thereby, the out-diffusion of the impurity in source and drain regions 17 is suppressed, lowering of the impurity concentration of source and drain regions 17 can be prevented, and it is effective for improvement in the electrical property of MOS transistor 10.

When there is no need of suppressing the out-diffusion of source and drain regions 17, annealing may be performed after removing silicon oxide film 60 of the source and drain region 17 upper surface.

When forming silicide layers 12a and 17a on the upper part of gate electrode 12 and source and drain regions 17, respectively, since it is necessary to deposit metal directly on gate electrode 12 and source and drain regions 17, in the case, it is needed to remove silicon oxide film 60 on gate electrode 12 and source and drain regions 17 by etching.

Except the step explained above, it is good to be the same as that of the manufacturing method in Embodiment 1.

What is claimed is:

1. A semiconductor device, comprising:
a semiconductor layer formed over an insulator layer;
an isolation insulating layer which is formed in the semiconductor layer and specifies an active region in the semiconductor layer concerned;
a transistor which has source and drain regions formed in the active region; and
a silicide layer formed in the source and drain region upper part of the transistor;
wherein
the isolation insulating layer has a portion which does not reach the insulator layer; and
the source and drain regions include a first and a second impurity ions with which mass numbers differ mutually.

2. A semiconductor device according to claim 1, wherein
the first impurity ion has a mass number smaller than the second impurity ion; and
in a boundary face of the silicide layer and the source and drain regions, a concentration of the first impurity ion is more than a concentration of the second impurity ion.

3. A semiconductor device according to claim 1, wherein
a bottom of the source and drain regions reaches even the insulator layer.

4. A semiconductor device according to claim 1, wherein
the semiconductor layer is 100 nm or less in thickness.

5. A semiconductor device according to claim 1, wherein
the first impurity ion is P ion; and
the second impurity ion is As ion.

6. A semiconductor device according to claim 1, wherein
the first impurity ion is B ion; and
the second impurity ion is In ion or BF₂ ion.

7. A method of manufacturing a semiconductor device, comprising the steps of:
(a) forming an isolation insulating layer which specifies an active region in a semiconductor layer to the semiconductor layer concerned formed over an insulator layer;
(b) forming a gate electrode of a transistor in the active region;
(c) forming source and drain regions of the transistor in the active region by implanting a first impurity ion with a comparatively small mass number, and a second impurity ion with a comparatively large mass number in an order of a small mass number;
(d) diffusing the first and the second impurity ions of the source and drain regions by heat treatment; and
(e) forming a silicide layer in the source and drain region upper part;
wherein
in the step (a), the isolation insulating layer is formed so that at least a portion may not reach even the insulator layer; and
implantation conditions of the first and the second impurity ions in the step (c) is set up so that a concentration of the first impurity ion may become more than a concentration of the second impurity ion in a boundary face of the silicide layer and the source and drain regions after the step (d) and (e).

8. A method of manufacturing a semiconductor device according to claim 7, further comprising a step of:
(f) after the step (b) and before the step (c), forming an oxide film over the semiconductor layer comprising the isolation insulating layer upper part;
wherein the implantation of the first and the second impurity ions in the step (c) is performed through the oxide film.

9. A method of manufacturing a semiconductor device according to claim 8, wherein
the heat treatment of the step (d) is performed in a state where the oxide film remains.

10. A method of manufacturing a semiconductor device according to claim 7, wherein
the first impurity ion is P ion; and
the second impurity ion is As ion.

11. A method of manufacturing a semiconductor device according to claim 7, wherein
the first impurity ion is B ion; and
the second impurity ion is In ion or BF₂ ion.
